(19) United States
(12) Patent Application Publication
(10) Pub. No.: US 2004/0067606 A1
(43) Pub. Date: Apr. 8, 2004

(54) Method for stack-packaging integrated circuit die using at least one die in the package as a spacer

(76) Inventors: Gerald K. Fehr, La Selva Beach, CA (US); Ernesto Alapit Opiniano, San Jose, CA (US)

Correspondence Address: CENTRAL COAST PATENT AGENCY, PO BOX 187, AROMAS, CA, 95004, US

(21) Appl. No.: 10/263,492

(22) Filed: Oct. 2, 2002

(51) Int. Cl. H01L 21/44; H01L 21/48; H01L 21/50

(52) U.S. Cl. 438/109; 438/127

(57) ABSTRACT

A method for producing a semiconductor package without spacer components has steps of (a) providing at least two rectangular die components each having a length greater than a width and bond pads implemented on the short sides only; (b) cross stacking the die components on a substrate for package assembly such that the bond-pad arrays are unobstructed; (c) wire bonding the unobstructed bond pads on each die component to the substrate; and (d) encapsulating the package.

### FIELD OF THE INVENTION

The present invention is in the field of semiconductor packaging including stack packaging of multiple die, and pertains more particularly to stacking die in a package without requiring use of a spacer between dies.

### BACKGROUND OF THE INVENTION

In the field of semiconductor packaging, manufacturers continue to work toward a goal of producing smaller, more powerful semiconductor components. One method for achieving more powerful components, such as memory components, for example, without increasing footprint requirements is to stack multiple die into one single package.

BGA and Chip Scale Packages are products that can and often do utilize more than one die. Typically die introduced into a package are same size die (dimensionally) and must be stacked together with spacers so that die pads are available and accessible to be wired for communication between the die and, for example, a circuit board. It has occurred to the inventor that if multiple die could be stacked together in a package without using spacers, more space reduction, especially in terms of vertical footprint, can be achieved, leading to yet smaller, more lightweight packages having as much or, because of the smaller footprint, more power than packages utilizing same size die interleaved with spacers.

Therefore, what is clearly needed is a method for symmetrically stacking die together in a package without requiring spacers between die. A method such as this would enable more memory and utility for small packages without requiring additional space.

### SUMMARY OF THE INVENTION

In a preferred embodiment of the present invention a method for producing a semiconductor package without spacer components is provided, comprising steps of (a) providing at least two rectangular die components each having a length greater than a width and bond pads implemented on the short sides only; (b) cross stacking the die components on a substrate for package assembly such that the bond-pad arrays are unobstructed; (c) wire bonding the unobstructed bond pads on each die component to the substrate; and (d) encapsulating the package.

In some embodiments, in step (a), the individual die components consist each of two or more identical die in a contiguous silicon unit, while in other preferred embodiments the individual die components consists of one rectangular die each.

In another aspect of the invention a semiconductor package is provided, comprising at least two die components with length greater than width and bond pads implemented on the short sides only, and a base substrate. The package is characterized in that the die components are cross-stacked face-up on the substrate, leaving all bond pads on the die components accessible to be wire-bonded to the substrate.

In some embodiments the individual die components consist each of two or more identical die in a contiguous silicon unit, and in other embodiments the individual die components consists of one rectangular die each.

In yet another aspect a semiconductor package is provided, comprising a substrate comprising two or more vias through the substrate, a first die component mounted to the substrate, face away from the substrate, within the outer periphery of the vias, a second die component bonded to the substrate with active face toward the substrate and bond pads exposed in the vias, and a third die component mounted to the second die component with active face away from the second die component. The package is characterized in that wires are bonded conventionally from bond pads to the substrate for the first and third die components, and through the vias for the second die component. IN some embodiments there is interposer connecting land pads on opposite sides of the substrate.

In various embodiments of the invention taught below in enabling detail, for the first time a method is provided that eliminates spacers in building packages comprising several like die.

### BRIEF DESCRIPTION OF THE DRAWING FIGURES

FIG. 1 is a stacked package using multiple die and spacers according to prior-art.

FIG. 2 is an overhead view of die-sets cross-positioned for stacking according to an embodiment of the present invention.

FIG. 3 is a broken view of die-sets stacked onto a substrate according to an embodiment of the present invention.

FIG. 4 is a broken view of a stacked package using no spacers.

FIG. 5 is an elevation of a flip chip package according to an embodiment of the invention.

### DESCRIPTION OF THE PREFERRED EMBODIMENTS

The inventor provides a method for producing a semiconductor package using mass-produced dies that can be stacked together without a requirement for spacing substrates placed between the dies in package assembly. The invention is described in enabling detail below.

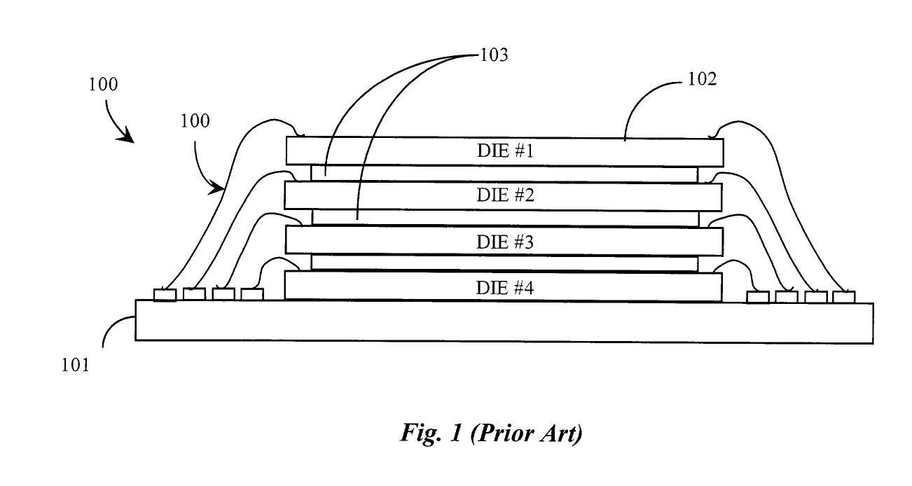

FIG. 1 is an elevation view of a typical multi-die package 100 according to prior-art. Package 100 comprises four identically sized die 102 also labeled DIE #1 through DIE #4. Die 102 are manufactured using typical semiconductor manufacturing techniques wherein identically sized die are formed on a wafer, then singulated into individual chips for packaging. It may be assumed in this example that each die 102 has multiple bond pads (not shown) provided as required, typically, around at least part of the periphery of each die.

Substrate spacers 103 separate die 102 from each other in package 100. In this prior-art example there are four die spaced apart from one another by three spacers. It is noted herein that the active side of each die 102 faces upward eliminating the need for a spacer between DIE #4 and a substrate 101 to which the die are mounted using standard wire bonding procedures. In this example die 102 are identical in footprint. Spacers 103 are required in this implementation because otherwise bond pads on the active sides of at least some die 102 would be inaccessible for wire bonding using such as wires 104. The vertical footprint of package 100 is extended, in this example, by the combined thickness of added spacers 103.

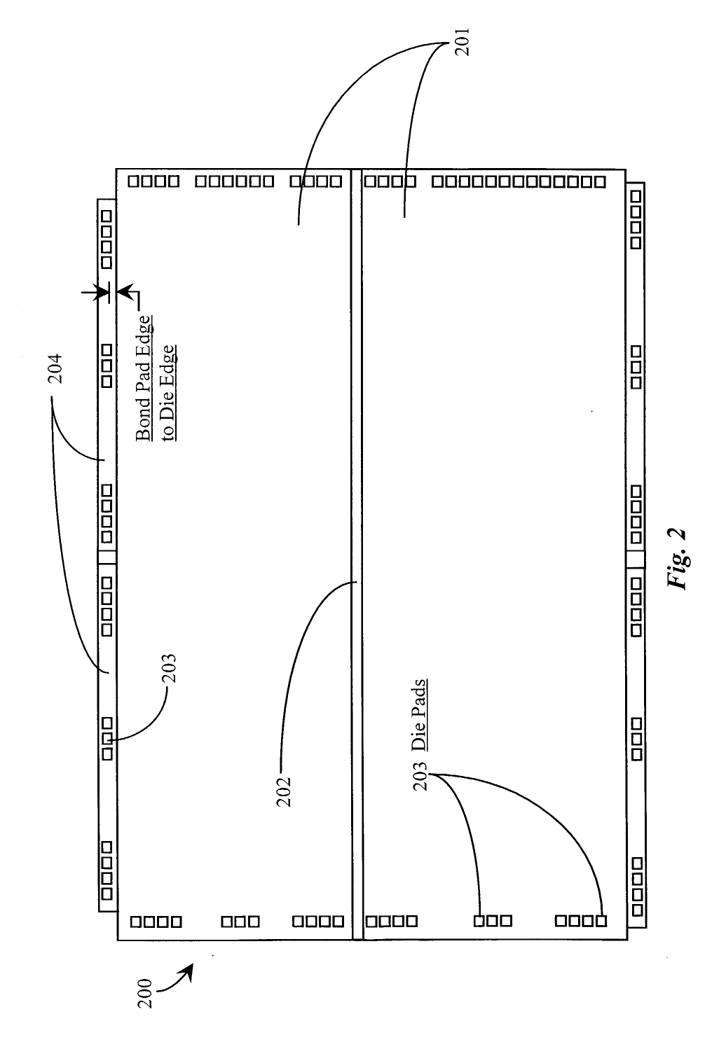

FIG. 2 is a plan view of die sets 200 in position for stacking according to an embodiment of the present invention. The invention in a preferred embodiment is particularly applicable for die having an aspect ratio greater than 2:1 for a single die, and having wire-bond pads on the short edges of the die. In this situation, a single die is more than twice as long as it is wide, and one may saw a wafer into die sets as shown in FIG. 2, having two die in a single set. The result is a single silicon contiguous die set (201, 204) wherein the length is just slightly greater than the width. Die-sets 200 comprise a top die set 201 and a bottom die set 204.

By cross positioning top die 201 and bottom die 204 in a stack, bond pads 203 on each die set remain accessible for wire bonding around the periphery of the stack. In this configuration, no spacer is required to separate die-sets 201 and 204 in a semiconductor package.

Stack 200 as illustrated in FIG. 2 apparently comprises only two die sets. There may well be any number more than two within the vertical range of ability to wire bond from upper sets in a stack to a substrate.

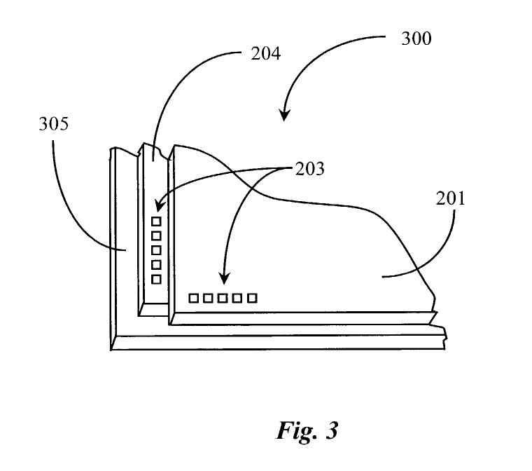

FIG. 3 is a broken perspective view of stacked die sets 201 and 204 from FIG. 2 on a substrate 305 according to an embodiment of the present invention. Stacked die package 300 in this example comprises a substrate 305, a bottom die set 204, and top die set 201. Accessibility to individual die pads 203 is accomplished by cross positioning the rectangular die in the stack. No spacer is required in this type of simple stack configuration.

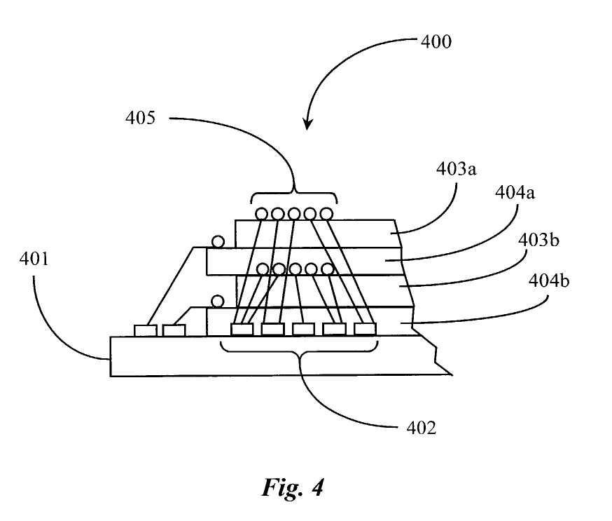

FIG. 4 is a broken elevation view of a stacked package 400 using four die sets and no spacers. Package 400 is stacked with four die sets 403a, 403b, 404a, and 404b. Dies sets 403a and b are positioned in the same direction exposing bond pad arrays 405. Bond-pad arrays are illustrated as connected by wire bonding to a substrate 401, typically with gold (Au) wire, to one or more terminals 402 provided on the substrate and adapted for the purpose. In other embodiments, via openings, conductive tapes, conductive bars, and other types of schemes may also be used to enable electronic path communication within a semiconductor package and between a package and circuit board. There are many possibilities.

The inventor intends that this example simply illustrate the possibility of stacking more than two die sets in a package without requiring spacer components for die separation in the package. A vertically stacked package such as package 400 saves considerable vertical space as compared to the prior-art example of FIG. 1, which also contains four die. The amount of space recovered is equal to the spacer height (plus adhiesive) multiplied by 3.

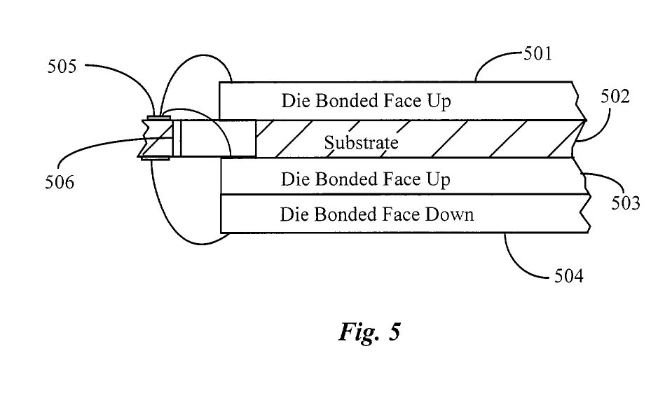

FIG. 5 is a broken elevation view of a flip-chip package 500 according to another embodiment of the invention. In this example, package 500 has three die or die sets 501, 503, and 504. Package 500 uses one substrate (502) and no spacers. Die 501 is bonded face or active side up on substrate 502 using adhesive adapted for the purpose. Die 503 is bonded face up to substrate 502 leaving pads exposed via opening 506 through the substrate. Die 504 is bonded face down to die 503. An interposer 505 provides a conductive interface that is bridged to both sides of substrate 502 though via 506. In this way, die 504 (face down) may be wire bonded to the underside of substrate 502 and still communicate with a solder ball connection (not shown) mounted to the upward facing surface of substrate 502.

In yet another embodiment, two-die sets may be stacked in place of die 502 and 503. In this case the die-sets may be bonded face down or with active sides facing each other because of the cross-positional configuration of the rectangular die. In an embodiment wherein dies 503 and 504 are two-die sets, they may also be stacked and bonded active side up in the same direction provided openings through substrate 502 are provided to expose the pads on die 503. The interposer described above functions in conjunction with signal traces to extend electrical communication to solder balls or bumps typically mounted for PCB assembly to a package like package 500.

It will be apparent to the skilled artisan that the exemplary use of two-die sets, as described with reference to FIGS. 1-4 is exemplary only, and not a limitation in the invention. Single die may be used as well, as long as the aspect ratio accounts for cross-stacking in a manner that leaves the wire-bond pads at the periphery of the stacked die exposed for bonding. It will also be apparent to the skilled artisan that the invention is particularly applicable to such as memory assemblies, wherein multiple die of the same type and footprint may be required in a single package.

One with skill in the art will recognize that there are many possible options for chip packaging using the die-sets of the present invention without departing from the spirit and scope of the present invention. Using the cross-positioning method, die in a flip chip may all face the same direction in terms of active side provided villas are present through the substrate where required for wire bonding.

The method and apparatus of the invention should be afforded the broadest scope under examination. The spirit and scope of the invention is limited only by the claims that follow.

What is claimed is:

1. A method for producing a semiconductor package without spacer components, comprising steps of:
(a) providing at least two rectangular die components each having a length greater than a width and bond pads implemented on the short sides only;
(b) cross stacking the die components on a substrate for package assembly such that the bond-pad arrays are unobstructed;
(c) wire bonding the unobstructed bond pads on each die component to the substrate; and
(d) encapsulating the package.

2. The method of claim 1 wherein, in step (a), the individual die components consist each of two or more identical die in a contiguous silicon unit.

3. The method of claim 1 wherein, in step (a), the individual die components consists of one rectangular die each.

4. A semiconductor package comprising:
at least two die components with length greater than width and bond pads implemented on the short sides only; and
a base substrate;
characterized in that the die components are cross-stacked face-up on the substrate, leaving all bond pads on the die components accessible to be wire-bonded to the substrate.

5. The package of claim 4 wherein the individual die components consist each of two or more identical die in a contiguous silicon unit.

6. The method of claim 1 wherein the individual die components consists of one rectangular die each.

7. A semiconductor package, comprising:
a substrate comprising two or more vias through the substrate;
a first die component mounted to the substrate, face away from the substrate, within the outer periphery of the vias;
a second die component bonded to the substrate with active face toward the substrate and bond pads exposed in the vias; and
a third die component mounted to the second die component with active face away from the second die component;
characterized in that wires are bonded conventionally from bond pads to the substrate for the first and third die components, and through the vias for the second die component.

8. The semiconductor package of claim 7 comprising an interposer connecting land pads on opposite sides of the substrate.
